(19) United States
(12) Patent Application Publication
(10) Pub. No.: US 2012/0214262 A1
(43) Pub. Date: Aug. 23, 2012

(54) Embedded Semiconductor Device Including Phase Changeable Random Access Memory Element and Method of Fabricating the Same

(75) Inventors: Teakwang Yu, Hwaseong-si (KR); Yongtae Kim, Yongin-si (KR); Byungsup Shim, Yongin-si (KR); Yongkyu Lee, Gwacheon-si (KR)

(73) Assignee: Samsung Electronics Co., Ltd.

(21) Appl. No.: 13/401,550

(22) Filed: Feb. 21, 2012

(30) Foreign Application Priority Data
Feb. 22, 2011 (KR) 10-2011-0015690

(51) Int. Cl. H01L 21/66

(52) U.S. Cl. 438/15; 257/E21.531

(57) ABSTRACT

Disclosed are an embedded semiconductor device including a phase changeable random access memory element and a method of fabricating the same. A semiconductor chip including a main memory element and a supplementary memory element is integrated on a substrate, intrinsic chip data are obtained by electrically testing the semiconductor chip, and the semiconductor chip is packaged. The intrinsic chip data are written into the supplementary memory element before the packaging of the semiconductor chip, and a memory layer of the supplementary memory element is formed of a material exhibiting an improved data retention property under thermal environmental conditions as compared with a memory layer of the main memory element.

### CROSS-REFERENCE TO RELATED APPLICATIONS

This U.S. non-provisional patent application claims priority under 35 U.S.C. §119 to Korean Patent Application No. 10-2011-0015690, filed on Feb. 22, 2011, in the Korean Intellectual Property Office, the entire contents of which are hereby incorporated by reference.

### BACKGROUND OF THE INVENTION

Embodiments of the inventive concept relate generally to a semiconductor device and a method of fabricating the same, More particularly, embodiments of the inventive concept relate to an embedded semiconductor device including a phase changeable random access memory element and a method of fabricating the same.

An embedded semiconductor device may include memory and logic elements integrated on a single chip. The embedded semiconductor device includes a main memory element configured to store user data and a functional circuit configured to process specific functions demanded by a user.

The main memory element is used to exhibit non-volatility so that the user data can be preserved even when power is not supplied thereto, Because a FLASH memory element can realize the non-volatility of information, it has been used for the main memory element of the conventional embedded semiconductor device. However, because the operation speed of the FLASH memory element is relatively slow, the conventional embedded semiconductor device has a limitation in meeting a demand for a fast operating speed.

### SUMMARY

Embodiments of the inventive concept provide an embedded semiconductor device allowing user data to be changed and read out.

Other embodiments of the inventive concepts provide a method of fabricating an embedded semiconductor device allowing user data to be changed and read out.

According to example embodiments of the inventive concepts, a method of fabricating a semiconductor device may include integrating a semiconductor chip on a substrate, the semiconductor chip including a main memory element and a supplementary memory element, electrically testing the semiconductor chip such that intrinsic chip data are written into the supplementary memory element, and packaging the semiconductor chip. The intrinsic chip data may be written in the supplementary memory element before the packaging of the semiconductor chip, and a memory layer of the supplementary memory element is formed of a material exhibiting improved thermal stability as, compared with a memory layer of the main memory element.

In some embodiments, the packaging of the semiconductor chip may include one or more operations performed at a temperature of at least about 200 degrees Celsius degree. In addition, the main memory element may include a layer of chalcogenide used as the memory layer thereof, and the supplementary memory element may include a layer formed of at least one of silicon oxide, silicon nitride, silicon oxynitride and polysilicon, which is used as the memory layer thereof.

In even other embodiments, the supplementary memory element may comprise one or more electrically programmable nonvolatile memory elements. In other embodiments, the supplementary memory element may comprise one or more electrically and one-time programmable nonvolatile memory elements.

In further embodiments, the semiconductor chip may further include functional circuits configured to process a user function. The main memory element may be configured to store user data provided by the user, and the supplementary memory element may be configured to store the intrinsic chip data associated with the semiconductor chip. The intrinsic chip data may include at least one of security code data and operational condition data.

In even further embodiments, the functional circuit may further include a metal-oxide-silicon transistor provided with a gate insulating layer, and the memory layer of the supplementary memory element may be formed of the same material as the gate insulating layer for one of the metal-oxide-silicon transistors.

In yet further embodiments, the semiconductor chip may further include at least one of a volatile random access memory configured to store data to be used in the functional circuit and a read-only memory configured to store invariant data. The invariant data may be stored in the read-only memory before the intrinsic chip data are written into the supplementary memory element.

In yet further embodiments, the method may further include testing characteristics of the semiconductor chip under a thermal environment between writing the intrinsic chip data into the supplementary memory element and the packaging of the semiconductor chip. The testing of the semiconductor chip under the thermal environment may include a bake step performed at a temperature of at least about 100 degrees Celsius.

According to other example embodiments of the inventive concept, a semiconductor device integrated with a memory structure and a non-memory structure is provided. Here, the non-memory structure may include functional circuits configured to process user functions and the memory structure may include main memory elements configured to store user data and including a memory layer formed of chalcogenide and supplementary memory elements configured to store intrinsic chip data of the semiconductor chip. The supplementary memory element may comprise at least one electrically programmable nonvolatile memory element, and a memory layer of the supplementary memory element may be formed of a material exhibiting an improved data retention property under thermal environmental conditions as compared with the memory layer of the main memory element.

In some embodiments, the memory layer of the supplementary memory element may be formed of a material capable of exhibiting a data retention property under a temperature of at least about 200 degrees Celsius. For example, the memory layer of the supplementary memory element may be formed of at least one of silicon oxide, silicon nitride, silicon oxynitride and polysilicon.

### BRIEF DESCRIPTION OF THE DRAWINGS

Example embodiments will be more clearly understood from the following brief description taken in conjunction with the accompanying drawings. FIGS. 1 through 15 represent non-limiting, example embodiments as described herein.

FIG. 1 is a flow chart exemplarily illustrating a method of fabricating a semiconductor device according to example embodiments of the inventive concept;

FIG. 2 is a schematic exemplarily illustrating elements constituting the semiconductor device according to example embodiments of the inventive concept;

FIG. 3 is a graph showing a relationship between crystalline structure and electric resistance of a phase changeable material according to temperature in a thermal treatment;

FIGS. 4 through 6 are sectional views exemplarily illustrating first memory elements of a first memory region according to example embodiments of the inventive concept;

FIGS. 7 and 8 are sectional views exemplarily illustrating non-memory elements of a functional circuit structure according to example embodiments of the inventive concept;

FIGS. 9 through 11 are sectional views exemplarily illustrating second memory elements of a second memory region according to example embodiments of the inventive concept;

FIGS. 12 and 13 are circuit diagrams exemplarily illustrating third memory elements of a third memory region according to example embodiments of the inventive concept;

FIG. 14 is a sectional view exemplarily illustrating a fourth memory element of a fourth memory region according to example embodiments of the inventive concept; and

FIGS. 15 through 17 are sectional views exemplarily illustrating a semiconductor device according to example embodiments of the inventive concept.

It should be noted that these figures are intended to illustrate the general characteristics of methods, structure and/or materials used in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout the description. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and this specification and will not be interpreted in an idealized or overly formal sense unless expressly so defined herein.

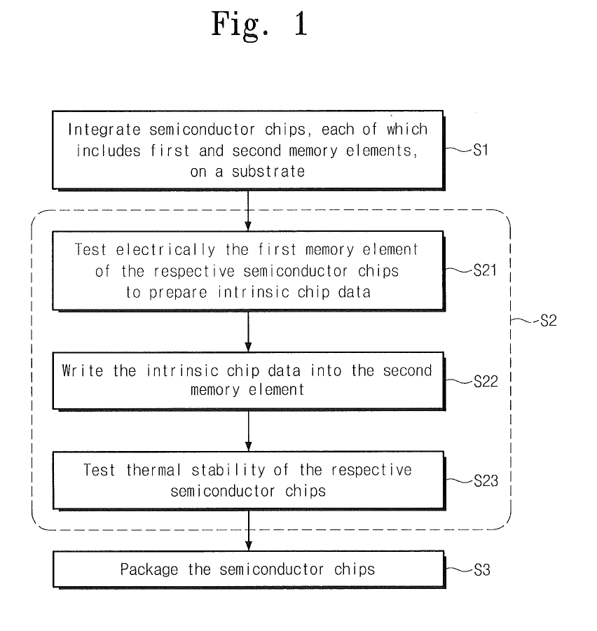

FIG. 1 is a flow chart exemplarily illustrating a method of fabricating a semiconductor device according to example embodiments of the inventive concept.

Referring to FIG. 1, semiconductor devices may be integrated on a semiconductor wafer (or a semiconductor substrate) (in S1) and be tested to determine whether it would work or not (in S2). Each of the tested semiconductor devices may be sold to users after a packaging process (in S3).

The test of the semiconductor devices S2 may include testing electrical characteristics of the respective semiconductor devices (in S21) and testing thermal stability of the respective semiconductor devices (in S23) as shown in FIG. 1. The test of thermal stability S23 may be performed under an accelerated environmental operating condition to verify a warranty or guarantee term of the semiconductor device. For example, the test of thermal stability S23 may include a bake step that is performed under a temperature condition of at least about 70 degrees Celsius. In addition, the test of the semiconductor devices S2 may further include a writing step of intrinsic chip data (in S22), which is performed between the steps S21 and S23 of testing electrical characteristics and thermal stability.

Each of the semiconductor devices may include a memory structure that includes first memory elements (or main memory elements) configured to store user data and second memory elements (or supplementary memory elements) configured to store the intrinsic chip data. The intrinsic chip data may be prepared by testing electrical characteristics of the semiconductor device (especially, the first memory elements) and be stored in the second memory element.

According to example embodiments of the inventive concept, the first memory elements may include at least one of material exhibiting a variable resistance property. For example, a memory layer of the first memory element may be formed of one or more phase changeable materials. By contrast, the second memory elements may include one or more electrically programmable nonvolatile memory elements exhibiting improved thermal stability compared with the first memory element.

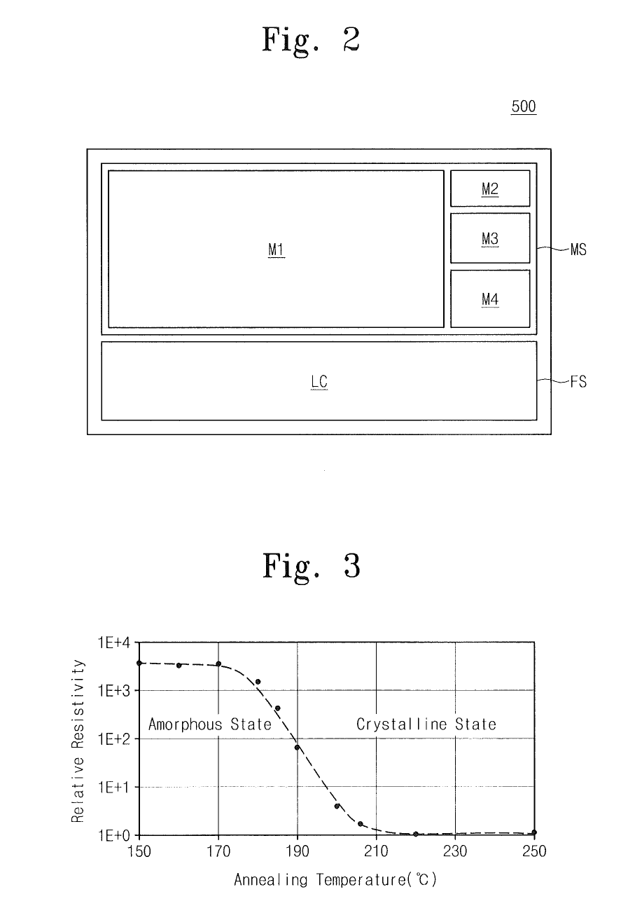

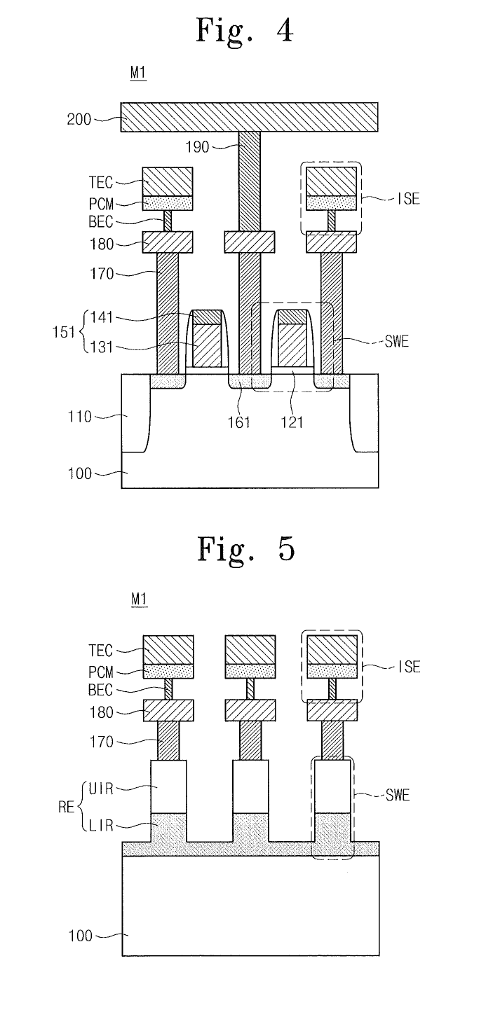

Hereinafter, some aspects or technical features associated with some elements of the semiconductor device will be described in more detail with reference to the exemplary embodiments of FIGS. 2 and 3. For instance, FIG. 2 is a schematic exemplarily illustrating elements constituting the semiconductor device according to example embodiments of the inventive concept, and FIG. 3 is a graph showing a relationship between crystalline structure and electric resistance of a phase changeable material according to temperature in a thermal treatment.

Referring to FIG. 2, each of the semiconductor devices 500, integrated on the semiconductor wafer, may include a memory structure MS comprising memory elements configured to store data. In some embodiments, each of the semiconductor devices 500 may further include a functional circuit structure FS comprising non-memory elements configured to process specific functions, thereby serving an embedded semiconductor device.

The memory structure MS may include a first memory region M1 configured to store user data (for example, a user ID, a password, images, and so forth) and a second memory region M2 configured to store intrinsic chip data. In addition, the memory structure MS may further include a third memory region M3 configured to temporarily store information processed by the functional circuit structure FS and/or a fourth memory region M4 configured to store specific invariant data.

The first memory region M1 may include a plurality of first memory elements and a first peripheral circuit for operating the first memory elements. According to example embodiments of the inventive concept, the first memory element may include one or more materials exhibiting a variable resistance property. In other words, the resistance of the first memory element may be selectively changed by an electric current passing through the first memory. For example, the memory layer of the first memory element may be formed of one or more materials (e.g., chalcogenide) whose crystalline structure or electric resistance can be changed by Joule's heat. Here, the chalcogenide may be a material containing at least one of antimony (Sb), tellurium (Te), and selenium (Se). In some embodiments, the first memory element may be one or more of the phase changeable memory elements exemplarily depicted in FIGS. 4 through 6.

The intrinsic chip data to be stored in the second memory region M2 may be information associated with the semiconductor device 500. For example, the intrinsic chip data may include a security code or operational condition data prescribing an operation condition required for properly operating the first memory elements. Accordingly, even in the stage before the semiconductor devices 500 are used by users, there is no reason that the semiconductor devices should have the same intrinsic chip data as each other.

In the case that the intrinsic chip data includes the security code or the operational condition data, the intrinsic chip data should be preserved until a warranty term guaranteed by a manufacturer. In this sense, the second memory region M2 for storing the intrinsic chip data may include one or more nonvolatile memory elements.

In addition, the memory elements of the second memory region M2 may have an improved thermal stability compared with the first memory elements. In more detail, as shown in FIG. 3, if a thermal treatment is performed at a temperature of about 180 degrees Celsius or more, crystalline structure and electric resistance of the phase changeable material may be changed. In other words, in the case that the phase changeable memory elements are included in the first memory region M1, a temperature environment of about 180 degrees Celsius or more may lead to a loss in data stored in the first memory region M1.

In the meantime, as described with reference to FIG. 1, the thermal stability test S23 and the packaging process S3 are performed after the writing of the intrinsic chip data. Here, the packaging process S3 may include a step performed under a temperature condition of about 200 degrees Celsius degree or more, and the thermal stability test S23 is performed under a high temperature condition (for example, at least about 70 degrees Celsius). Thus, in the case that the intrinsic chip data are written in the first memory region M1, the intrinsic chip data may be lost during the packaging process S3 or the thermal stability test S23. However, according to example embodiments of the inventive concept, the intrinsic chip data are stored not in the first memory region M1 but in the second memory region M2, which consists of memory elements exhibiting an improved thermal stability compared with the first memory region M1, and this may prevent the intrinsic chip data from being lost.

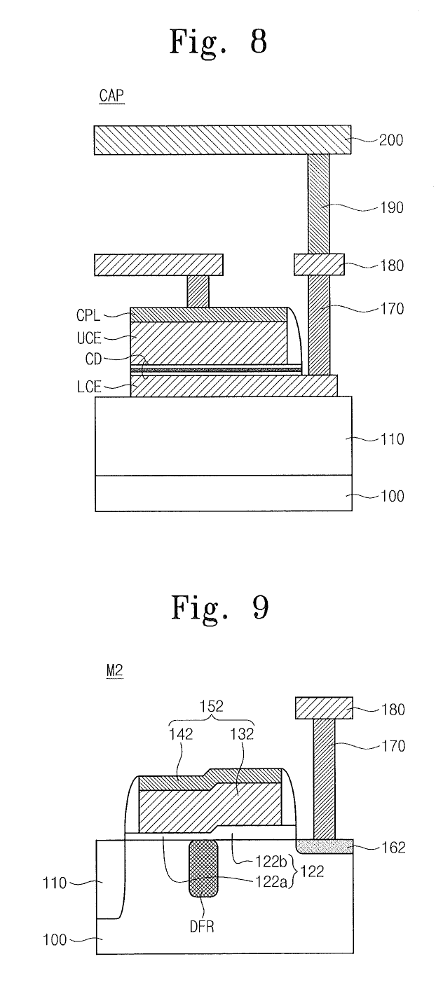

In summary, in some embodiments, the second memory region M2 may include nonvolatile memory elements that exhibit an improved thermal stability or heat-resistance property compared with the phase changeable material. In some embodiments, one or more memory elements, which will be described in further detail with reference to FIGS. 9 through 11, may be used as such nonvolatile memory elements for the second memory region M2. But example embodiments of the inventive concept may not be limited thereto, and they may be variously modified on the basis of the following description.

Furthermore, as described with reference to FIG. 1, the intrinsic chip data (especially, the operational condition data) may be written in the second memory region M2 by using an electrical method during the writing step of the intrinsic chip data S22. In this sense, the memory elements of the second memory region M2 may be electrically programmable. To sum up, the second memory region M2 may include memory elements capable of satisfying one or more of the following three requirements: i) improved thermal stability or heat-resistance property, compared with the phase changeable material, ii) data nonvolatility, and iii) an electrically programmable property. In some embodiments, the memory elements of the second memory region M2 may be configured to have a one-time-programmable property in addition to the three requirements.

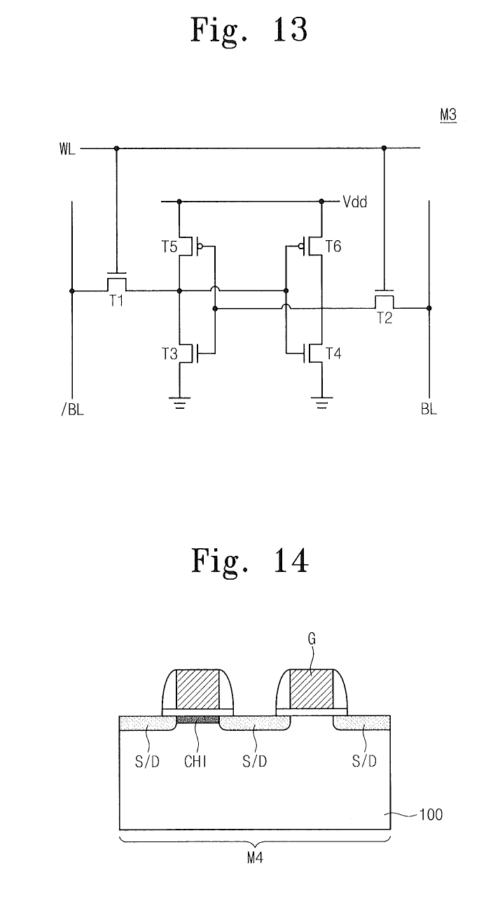

The memory elements of the third and fourth memory regions M3 and M4 may differ from the memory elements of the first and second memory regions M1 and M2 in terms of operation principle and/or structure. For example, the third memory region M3 may include volatile random access memory (RAM) elements, such as a DRAM shown in FIG. 12 or an SRAM shown in FIG. 13. Alternatively, the memory elements of the fourth memory region M4 may be a memory element, such as a read only memory (ROM) shown in FIG. 14.

Meanwhile, the fourth memory region M4 may be used to store invariant information (for instance, operating program or information associated thereto) that is independent of a result of the electrical test S21. Such invariant information may be written before performing the test of the semiconductor devices S2 in a manufacturing line or factory where the semiconductor device is fabricated. For example, in a portion of ROMs of the fourth memory region M4 a channel doped region CHI connecting source and drain regions S/D with each other may be formed in a channel region as shown in FIG. 14. In this sense, the memory elements of the fourth memory region M4 can be distinguished from the second memory region M2 comprising electrically programmable memory elements.

In conclusion, the memory elements of the second memory region M2 may differ from the memory elements of the fourth memory region M4 or the volatile memory elements of the third memory region M3 in terms of information-storing principle and/or a structure for storing information.

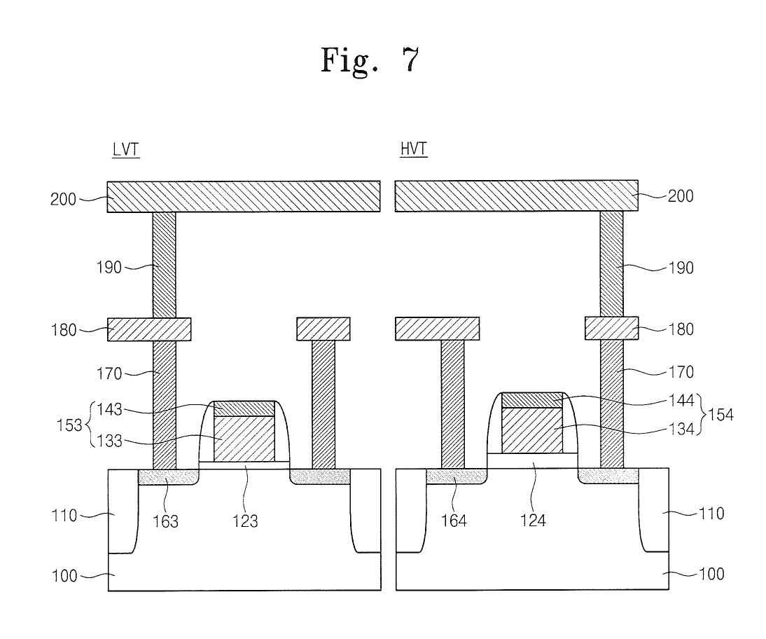

The functional circuit structure FS may include a logic circuit or an analog circuit, which may be configured to process specific functions demanded by a user. In some embodiments, the logic circuit may include a low voltage transistor LVT and a high voltage transistor HVT, as exemplarily depicted in FIG. 7, and the analog circuit may include a capacitor structure CAP, as exemplarily depicted in FIG. 8, including a pair of capacitor electrodes LCE and UCE and a capacitor dielectric CD interposed therebetween. The low voltage and high voltage transistors LVT and HVT and the capacitor structure CAP will be described below in more detail.

In some embodiments, the memory structure MS may include memory peripheral circuits, which are configured to operate the memory elements, not to store any data. For example, the first peripheral circuit of the first memory region M1 may be one of such memory peripheral circuits. The memory peripheral circuits may be similar to the logic circuit or the analog circuit of the functional circuit structure FS in that they are non-memory elements. However, the memory peripheral circuit is configured to control operations of the memory elements of the memory structure MS (for example, a read or write operation), and in this sense, it can be distinguished from the circuits of the functional circuit structure FS configured to process a user-demanding function (for example, computation).

In addition, the non-memory elements of the functional circuit structure FS can be distinguished from the non-memory elements of the memory peripheral circuit, in terms of their position. For example, the first peripheral circuit may be disposed within the first memory region M1 or disposed adjacent to the first memory elements compared with the functional circuit structure FS.

FIGS. 4 through 6 are sectional views exemplarily illustrating the first memory elements of the first memory region M1 according to example embodiments of the inventive concept.

Referring to FIGS. 4 through 6, each of the first memory elements may include information storing elements ISE disposed on the semiconductor substrate 100, and each of the information storing elements ISE may include a lower electrode BEC, an upper electrode TEC, and a phase changeable material layer PCM interposed therebetween. Electrical access to the information storing element ISE can be controlled by selecting the corresponding one of bit lines and the corresponding one of word lines, and for this selective access there may be a switching element SWE that is disposed between the information storing element ISE and the word line and is controlled by the word line.

The phase changeable material layer PCM may be formed of chalcogenide. In some embodiments, the phase changeable material layer PCM may be a chalcogenide formed of tellurium (Te) having about 20 to about 80 atomic percent concentration, antimony (Sb) having about 5 to about 50 atomic percent concentration, and germanium (Ge) having the remaining concentration. In addition, the phase changeable material layer PCM may further include at least one of the following materials N, O, C, Bi, In, B, Sn, Si, Ti, Al, Ni, Fe, Dy, or La as an impurity. In other embodiments, the phase changeable material layer PCM may be formed one of GeBiTe, InSb, GeSb, and GaSb.

According to the embodiments exemplarily shown in FIG. 4, the switching element SWE may be a MOS-type field effect transistor that uses the semiconductor substrate 100, a first gate pattern 151 on the semiconductor substrate 100, and first doped regions 161 in the semiconductor substrate 100 as a channel region, a gate electrode, and source/drain electrodes, respectively. In addition, a first gate insulating layer 121 may be interposed between the first gate pattern 151 and the semiconductor substrate 100.

One of the source/drain electrodes (i.e., the first doped regions 161) may be electrically connected to an upper interconnection line 200 crossing the information storing element ISE and the gate pattern 151 via an interconnection line structure. The interconnection line structure may include a lower plug 170, an upper plug 190 and a conductive pad 180 interposed therebetween, and the upper interconnection line 200 may serve as the bit line.

According to the embodiments exemplarily shown in FIG. 5, the switching element SWE may be a rectifying element RE. For example, the switching element SWE may be a pn-diode including a lower doped region LIR and an upper doped region UIR whose conductivity types are different from each other. The lower doped region LIR may serve as the word line and be formed to have a line shape in the semiconductor substrate 100. The upper doped region UIR may be formed to have an island shape and be in direct contact with a top surface of the lower doped region LIR.

The information storing element ISE may be coupled with the upper doped region UIR using the interconnection line structure. For example, as shown, the lower plug 170 and the conductive pad 180 may be used to electrically connect the upper doped region UIR to the information storing element ISE. The upper electrode TEC may be formed to have a line shape crossing the lower doped region LIR, and thus it may be used as the bit line.

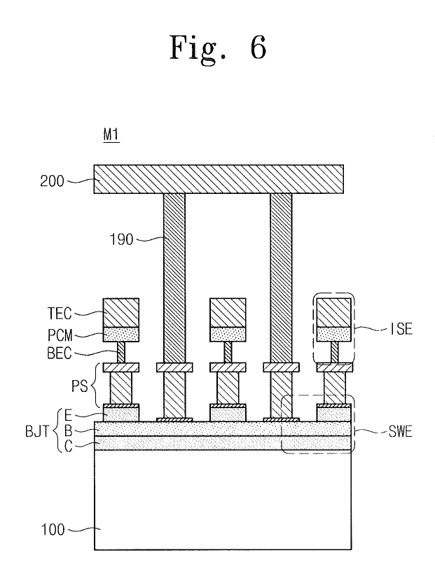

According to the embodiments exemplarily shown in FIG. 6, the switching element SWE may be a bipolar transistor BJT. For example, the switching element SWE may include doped regions used as a collector C, an emitter E, and a base B interposed therebetween, where the conductivity type of the collector C is the same as that of the emitter E and is different from that of the base B. The information storing element ISE may be coupled with the bipolar transistor BJT via a plug structure PS.

FIGS. 7 and 8 are sectional views exemplarily illustrating the non-memory elements of the functional circuit structure FS according to some embodiments of the inventive concept.

Referring to FIG. 7, the functional circuit structure FS may include a low voltage transistor LVT and a high voltage transistor HVT. The low voltage transistor LVT may include a low voltage gate pattern 153 on an active region, a low voltage gate insulating layer 123 interposed between the active region and the low voltage gate pattern 153, and a low voltage doped region 163 formed in the active region. The active region may be defined by a device isolation pattern 110 provided in the semiconductor substrate 100. The high voltage transistor HVT may include a high voltage gate pattern 154 on the semiconductor substrate 100, a high voltage gate insulating layer 124 interposed between the semiconductor substrate 100 and the high voltage gate pattern 154, and a high voltage doped region 164 formed in the semiconductor substrate 100.

In some embodiments, the low voltage gate pattern 153 may include a lower gate pattern 133 and an upper gate pattern 143, and the high voltage gate pattern 154 may include a lower gate pattern 134 and an upper gate pattern 144. The lower gate patterns 133 and 134 of the low voltage and high voltage gate patterns 153 and 154 may be formed to have the same material or layer structure as each other. The high voltage gate insulating layer 124 may be thicker than the low voltage gate insulating layer 123. Each of the low voltage and high voltage doped regions 163 and 164 may be connected to the corresponding one of the interconnection line structures.

Referring to FIG. 8, the functional circuit structure FS may include a capacitor structure CAP connected to the interconnection line structure. The capacitor structure CAP may include a lower capacitor electrode LCE, an upper capacitor electrode UCE, and a capacitor dielectric CD interposed between the lower and upper capacitor electrodes LCE and the UCE. In some embodiments, the capacitor dielectric CD may include at least one of the materials silicon oxide, silicon nitride, silicon oxynitride, aluminum oxide or hafnium oxide. For example, the capacitor dielectric CD may include a silicon oxide layer, a silicon nitride layer, and a silicon oxide layer sequentially stacked.

As shown in FIG. 8, a conductive capping layer CPL may be interposed between the upper capacitor electrode UCE and the interconnection line structure. In addition, the capacitor structure CAP may be formed on the device isolation pattern 110. According to modified embodiments, a doped region (not shown) serving as the lower capacitor electrode LCE may be formed in the semiconductor substrate 100.

FIGS. 9 through 11 are sectional views exemplarily illustrating the second memory elements of the second memory region M2 according to some embodiments of the inventive concept.

Referring to FIG. 9, the second memory element may include a second gate pattern 152 disposed on the semiconductor substrate 100 and a second gate insulating layer 122 interposed between the second gate pattern 152 and the semiconductor substrate 100. A second doped region 162 may be formed at one side of the second gate pattern 152 and be coupled with the interconnection line structure.

The second gate insulating layer 122 may include a thin portion 122a and a thick portion 122b located between the thin portion 122a and the second doped region 162. In addition, a defect region DFR may be locally formed below the second gate insulating layer 122.

In operation, if the second gate pattern 152 is connected to a high voltage sufficient to cause a breakdown at the second gate insulating layer 122, the second memory element may serve as a resistor. However, if such oxide breakdown does not occur, the second gate pattern 152 and the second doped region 162 may serve as a capacitor preventing a direct current from being transferred.

In some embodiments, the thin portion 122a and the thick portion 122b of the second gate insulating layer may be formed to have the same material as and/or the same thickness as the low voltage gate insulating layer 123 and the high voltage gate insulating layer 124, respectively, described with reference to FIG. 7. In addition, the second gate pattern 152 may be formed to have the same material as and/or the same layer-structure as at least one of the low voltage and high voltage gate patterns 153 and 154.

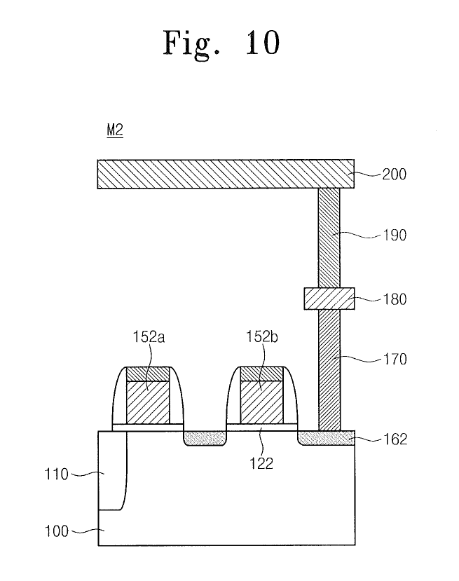

Referring to FIG. 10, the second memory element may include a pair of second gate patterns 152a and 152b disposed on the semiconductor substrate 100 and a second gate insulating layer 122 interposed between the second gate patterns 152a and 152b and the semiconductor substrate 100. In addition, a pair of second doped regions 162 may be formed at both sides of a selection gate 152b that is one of the second gate patterns. Hereinafter, the other one of the second gate patterns (i.e., 152a) will be called ‘write gate’. One of the second doped regions 162 may be connected to the interconnection line structure and the other may be in a floating state.

The selection gate 152b may be configured to selectively invert an energy level of a channel region thereunder. Accordingly, the floated second doped region 162 may be electrically and selectively connected to the interconnection line structure depending on a voltage applied to the selection gate 152b.

In operation, if the write gate 152a is connected to a high voltage sufficient to cause a breakdown at the second gate insulating layer 122 thereunder, the second gate insulating layer 122 may serve as a resistor. However, if such oxide breakdown does not occur, the second gate insulating layer 122 disposed under the write gate 152a may serve as a capacitor preventing a direct current from being transferred.

In some embodiments, the second gate insulating layer 122 may be formed to have the same material as and/or the same thickness as one of the low voltage gate insulating layer 123 and the high voltage gate insulating layer 124 described with reference to FIG. 7. In addition, the second gate patterns 152 may be formed to have the same material as and/or the same layer-structure as at least one of the low voltage and high voltage gate patterns 153 and 154.

The second memory element may be a charge storing type nonvolatile memory element. For example, as shown in FIG. 10, the second memory element may be a trap-type nonvolatile memory element, in which an insulating layer having many charge-trap sites is used as a charge trap gate insulating layer CS. In some embodiments, the charge trap gate insulating layer CS may be formed to have the same material as and/or the same layer-structure as the capacitor dielectric CD described with reference to FIG. 8.

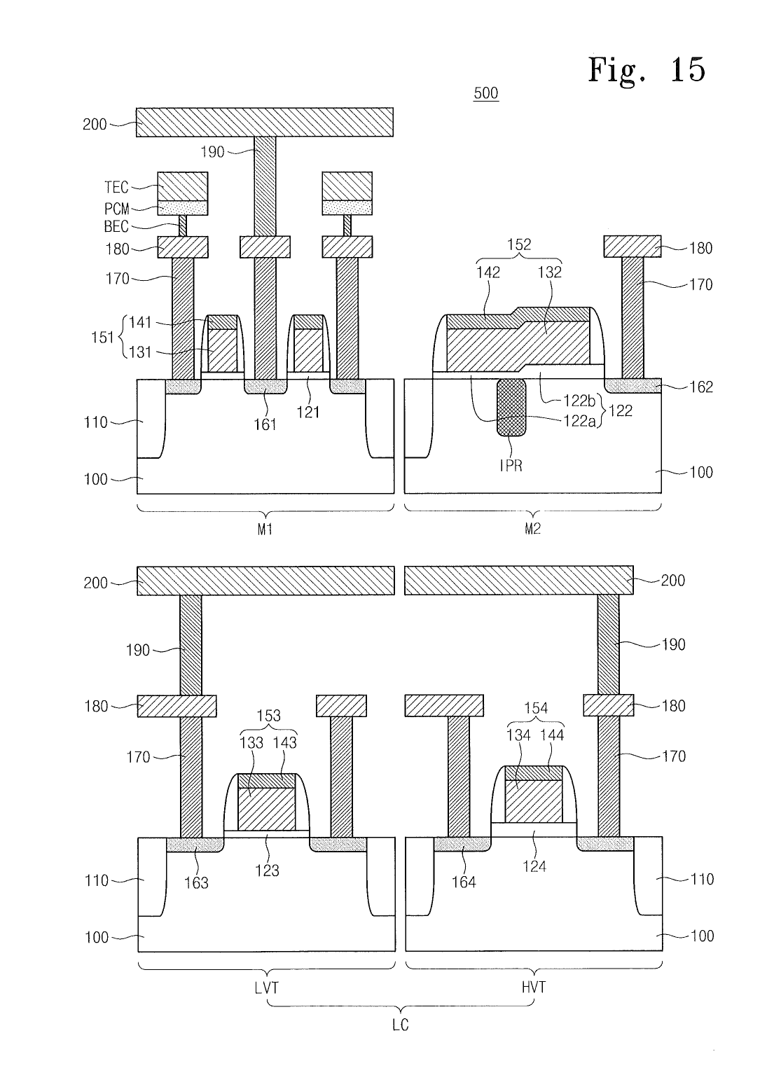

The devices or transistors described with reference to FIGS. 4 through 11 may constitute a semiconductor device according to example embodiments of the inventive concept. Hereinafter, such semiconductor devices will be exemplarily described with reference to FIGS. 15 through 17. However, for concise description, overlapping description of elements previously described with reference to FIGS. 4 through 11 may be omitted.

Referring to FIG. 15, the first memory region M1 of the semiconductor device 500 may include the first memory element described with reference to FIG. 4, and the second memory region M2 may include the second memory element described with reference to FIG. 9, and the functional circuit structure FS may include the low voltage and high voltage transistors LVT and HVT described with reference to FIG. 7.

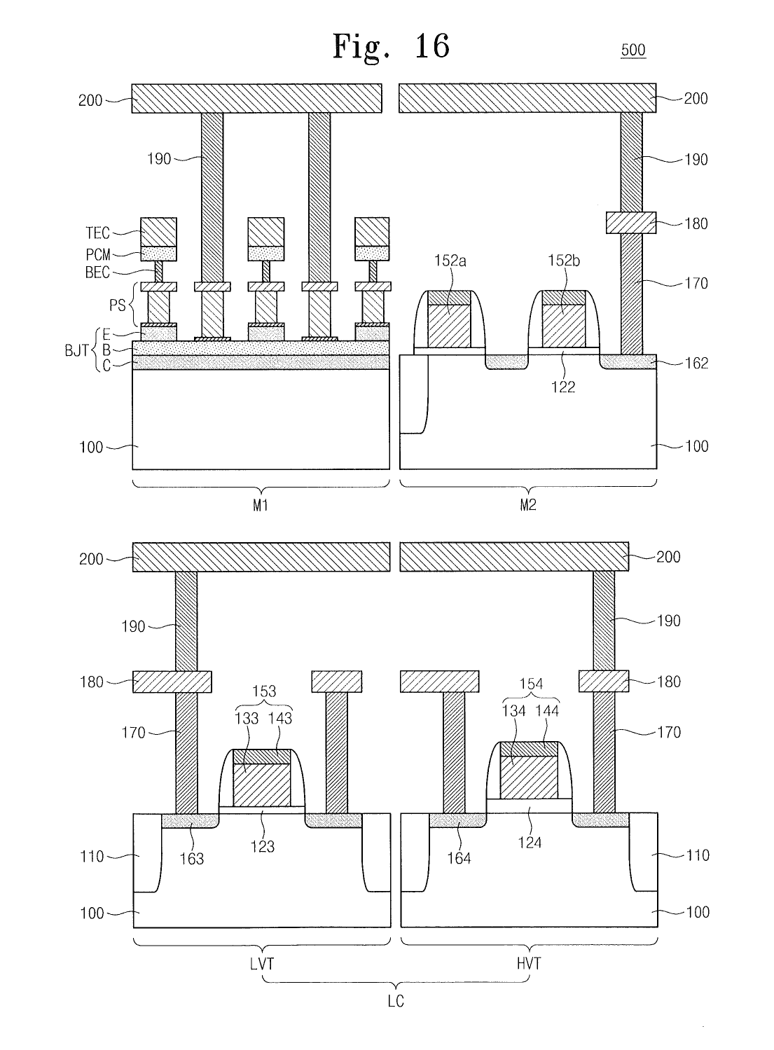

Referring to FIG. 16, the first memory region M1 of the semiconductor device 500 may include the first memory element described with reference to FIG. 5, and the second memory region M2 may include the second memory element described with reference to FIG. 10, and the functional circuit structure FS may include the low voltage and high voltage transistors LVT and HVT described with reference to FIG. 7.

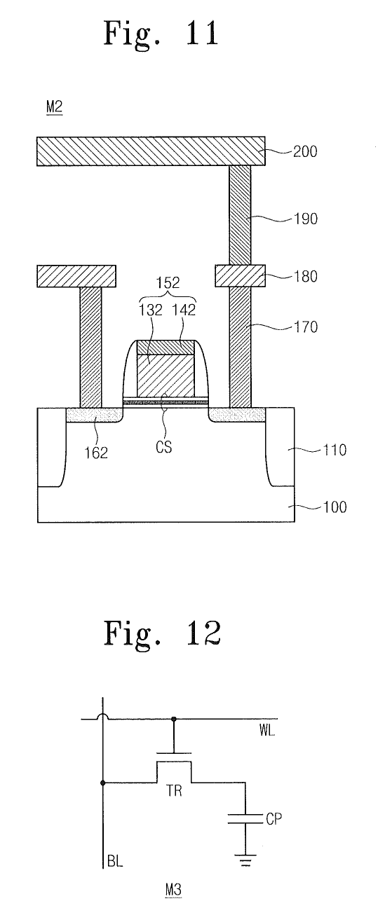

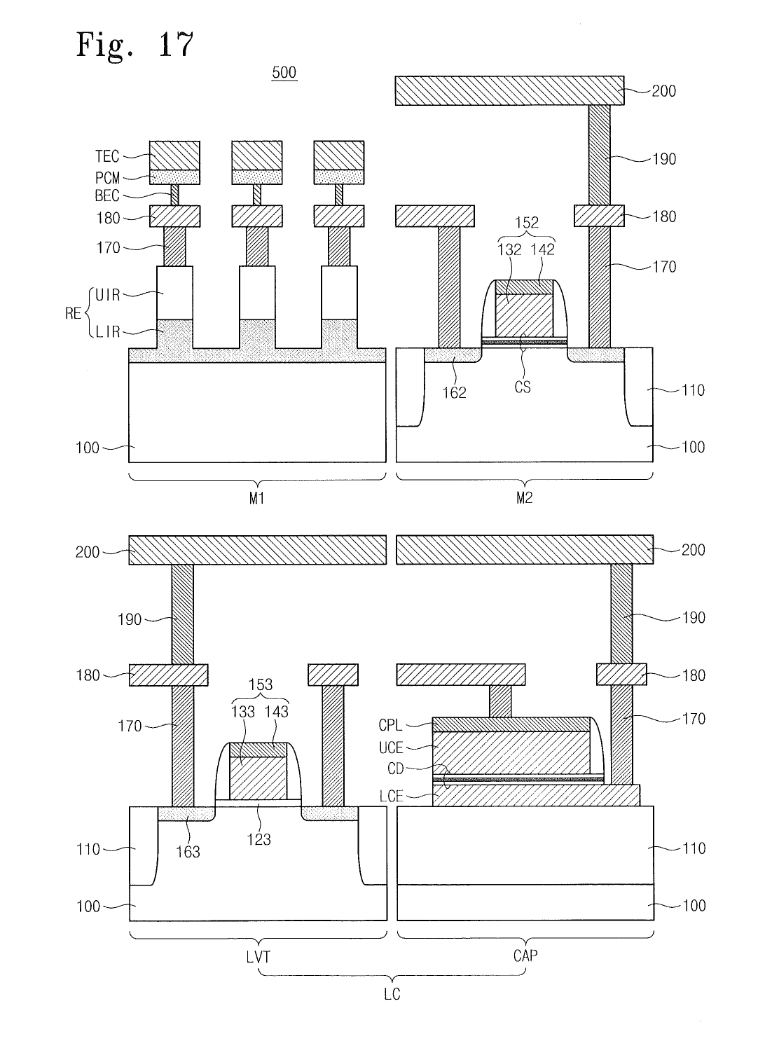

Referring to FIG. 17, the first memory region M1 of the semiconductor device 500 may include the first memory element described with reference to FIG. 6, and the second memory region M2 may include the second memory element described with reference to FIG. 11, and the functional circuit structure FS may include the low voltage and high voltage transistors LVT and HVT described with reference to FIG. 7 and the capacitor structure CAP described with reference to FIG. 8.

According to example embodiments of the inventive concepts, a phase changeable memory element is used as a main memory element for storing user data in an embedded semiconductor device. Accordingly, operations of changing or reading out the user data can be quickly performed in the embedded semiconductor device according to example embodiments of the inventive concept.

In addition, an electrically programmable nonvolatile memory element is used as a supplementary memory element for storing intrinsic chip data, such as security code data or operational condition data. Here, a memory layer of the supplementary memory element may be formed of a material exhibiting an improved thermal stability compared with that of the main memory element. Accordingly, during a thermal stability test or a packaging process, it may be possible to prevent or reduce the likelihood of a loss of the intrinsic chip data, which may occur when the intrinsic chip data are stored in a phase changeable memory element. As a result, the embedded semiconductor device can be realized in such a way that a phase changeable memory element is used as the main memory element.

While example embodiments of the inventive concepts have been particularly shown and described, it will be understood by one of ordinary skill in the art that variations in form and detail may be made therein without departing from the spirit and scope of the attached claims.

1. A method of fabricating a semiconductor device, comprising:
integrating a semiconductor chip on a substrate, the semiconductor chip including a main memory element and a supplementary memory element;
electrically testing the semiconductor chip such that intrinsic chip data are written into the supplementary memory element; and
packaging the semiconductor chip;
wherein the intrinsic chip data is written in the supplementary memory element before the packaging of the semiconductor chip, and a memory layer of the supplementary memory element is formed of a material exhibiting improved thermal stability as compared with a memory layer of the main memory element.

2. The method of claim 1, wherein the packaging of the semiconductor chip is performed at least partially at a temperature of at least 200 degrees Celsius.

3. The method of claim 1, wherein the memory layer of the main memory element comprises chalcogenide.

4. The method of claim 1, wherein the memory layer of the supplementary memory element comprises silicon oxide, silicon nitride, silicon oxynitride and/or polysilicon.

5. The method of claim 1, wherein the supplementary memory element comprises at least one electrically programmable nonvolatile memory element.

6. The method of claim 1, wherein the supplementary memory element comprises at least one electrically and one-time programmable nonvolatile memory element.

7. The method of claim 1, wherein the semiconductor chip further comprises functional circuits configured to process a user function;
wherein the main memory element is configured to store user data provided by the user.

8. The method of claim 7, wherein the intrinsic chip data comprises at least one of security code data and operational condition data.

9. The method of claim 7, wherein each of the functional circuits comprises a metal-oxide-silicon transistor provided with a gate insulating layer; and
wherein the memory layer of the supplementary memory element is formed of the same material as the gate insulating layer for one of the metal-oxide-silicon transistors.

10. The method of claim 7, wherein the semiconductor chip further comprises at least one of a volatile random access memory configured to store data to be used in the functional circuits and a read-only memory configured to store invariant data; and
wherein the invariant data is stored in the read-only memory before the intrinsic chip data are written into the supplementary memory element.

11. The method of claim 1, further comprising:
testing characteristics of the semiconductor chip under a thermal environment between writing the intrinsic chip data into the supplementary memory element and the packaging of the semiconductor chip;
wherein the testing of the semiconductor chip under the thermal environment comprises baking the semiconductor chip at a temperature of at least about 100 degrees Celsius.

12.-20. (canceled)
